(19) United States
(12) Patent Application Publication
(10) Pub. No.: US 2009/0050895 A1
(43) Pub. Date: Feb. 26, 2009

(54) SEMICONDUCTOR MANUFACTURING METHOD, SEMICONDUCTOR MANUFACTURING APPARATUS, AND DISPLAY UNIT

(75) Inventors: Akihiko Hiroe, Miyagi (JP); Akinobu Teramoto, Miyagi (JP); Tadahiro Ohmi, Sendai-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignees: TOKYO ELECTRON LIMITED, Tokyo (JP); NATIONAL UNIVERSITY CORPORATION TOHOKU UNIVERSITY, Sendai-shi (JP)

(21) Appl. No.: 12/195,508

(22) Filed: Aug. 21, 2008

(30) Foreign Application Priority Data
Aug. 24, 2007 (JP) 2007-218871

(51) Int. Cl. H01L 29/04; H01L 21/336; H01L 21/67

(52) U.S. Cl. 257/72; 438/151; 29/25.01; 257/E29.004; 257/E21.411

(57) ABSTRACT

In a semiconductor manufacturing method that manufactures a coplanar type thin film transistor, a microcrystalline film 10 that will become a channel region is formed on a glass substrate S, a sacrificial silicon oxide 20 film is formed on the microcrystalline film 10, and, in a state in which a surface boundary of the microcrystalline film 10 is protected by the sacrificial silicon oxide film 20, a doped silicon film 30 is built up that will become a source region and a drain region. A photoresist R film is applied on the doped silicon film 30 and planarized. With the sacrificial silicon oxide film 20 in an uncovered state, etching is performed until the microcrystalline film 10 and the doped silicon film 30 reside in approximately the same plane.

### CROSS REFERENCES TO RELATED APPLICATIONS

The present invention contains subject matter related to Japanese Patent Application JP 2007-218871 filed in the Japan Patent Office on Aug. 24, 2007, the entire contents of which being incorporated herein by reference.

### BACKGROUND OF THE INVENTION

1. Field of the Invention

The present invention relates to a semiconductor manufacturing method for manufacturing a thin film transistor, a semiconductor manufacturing apparatus that uses the semiconductor manufacturing method to manufacture the thin film transistor, and a display unit that incorporates the thin film transistor that is manufactured by the semiconductor manufacturing apparatus.

2. Description of the Related Art

In the formation of source and drain regions in a semiconductor using known technology, a process is performed in which ions of impurities that are output from an ion injection unit are embedded in the semiconductor by accelerating them at high energy and annealed such that the injected impurities are diffused.

As displays have become larger in recent years, there has been a rapid increase in the surface areas of the substrates that are used in them. The larger surface area makes it more difficult for the ion injection and the annealing to achieve uniform diffusion of the impurities over the entire surface of the substrate. Furthermore, the annealing process is a process that heats the device to a temperature of 600° C. or greater for at least several minutes, so the materials that can be used for the substrate are limited to those that will not melt during the annealing process. When quartz with a high melting point is used for the substrate, for example, it does not melt during the annealing process, but the cost rises considerably as the surface area increases. A glass substrate is inexpensive and thus suitable for a substrate with a large surface area, but due to the deformation temperature of glass, the maximum processing temperature is restricted to no greater than 600° C.

Accordingly, a method for forming a coplanar thin film transistor has been conceived that, instead of performing the ion injection and annealing processes, first forms a channel layer, then, by a chemical vapor deposition (CVD) process that uses a plasma, deposits a doped silicon layer into which impurities are infused. The active regions (the channel region and the source and drain regions) are planarized by etch back, such that the transistor has a structure in which the source region and the drain region are provided directly alongside the channel region.

### SUMMARY OF THE INVENTION

However, this method causes damage to the surface boundaries of the active regions (particularly the channel region) during the etch back, such that the characteristics of the active regions become worse. This occurs because, during the etch back, ions that are contained in the plasma attack the surface boundary of the channel region, causing defects within the grain boundaries of silicon particles, or grains. The defects within the grain boundaries impede the transport of the carrier and reduce its mobility. The defects within the grain boundaries also affect the threshold voltage of the device. Specifically, when the gate voltage is applied, the defects act as traps, reducing the on-off ratio (the ratio of the electric current that flows when the gate voltage Vg is zero volts (the off current) to the electric current that flows when the gate voltage Vg is a specified voltage (the on current: the saturation current)) and making it necessary to use a large electric current to turn the electric current flowing through the circuit on and off. If the gate voltage Vg is set extremely high to produce the large current, the gate insulation may be destroyed.

In order to address these issues, the present invention provides a semiconductor manufacturing method for protecting the surface boundary of the channel region during the manufacturing of the thin film transistor, a semiconductor manufacturing apparatus that uses the semiconductor manufacturing method to manufacture the thin film transistor, and a display unit that incorporates the thin film transistor that is manufactured by the semiconductor manufacturing apparatus.

Accordingly, an embodiment of the present invention addresses these issues and provides a semiconductor manufacturing method for manufacturing at least one of a coplanar type n-channel thin film transistor and a coplanar type p-channel thin film transistor. The semiconductor manufacturing method includes a first process, a second process, and a third process. The first process forms, on a substrate, a first active layer that becomes a channel region. The second process forms a dummy layer on the first active layer. With a surface boundary of the first active layer in a state of being protected by the dummy layer, the third process builds up a second active layer that becomes a source region and a drain region.

In the coplanar type n-channel thin film transistor (TFT) and the coplanar type p-channel thin film transistor, the second active layer that becomes the source and drain regions is generally built up after the formation of the first active layer that becomes the channel region.

However, if layers that are necessary for the thin film transistor are built up one after another on top of the first active layer while the surface boundary of the first active layer is an uncovered state, and if processes are then performed that remove unnecessary portions by etching and ashing, the attacks by the ions in the plasma and the like will cause damage to the surface boundary of the first active layer (the channel region) during the processing, such that the characteristics of the active regions become worse.

The present invention addresses this issue by forming the first active layer that becomes the channel region (the first process), then forming the dummy layer that protects the first active layer directly on the first active layer (the second process) and building up the second active layer that becomes the source and drain regions (the third process) after the dummy layer is formed. In this configuration, the dummy layer absorbs the ill effects that are imparted from the outside during the manufacture of the thin film transistor, such that the surface boundary of the first active layer incurs no damage during the process.

In particular, in the manufacture of the coplanar type thin film transistor, after the second active layer is built up, a photoresist film is applied on the second active layer and the applied photoresist film is planarized (a fourth process). Then, in a state in which the dummy layer is uncovered, an etching process is performed under specified conditions until the first active layer and the second active layer reside in approximately the same plane (a fifth process).

If the dummy layer, which is a sacrificial film, did not exist on top of the first active layer while the etching is being performed by the fifth process, the surface boundary of the channel region, which is the most important region, would be uncovered during the process. This would cause damage to a surface boundary between the first active layer and an insulator layer, which will be described later, such that the characteristics of the active regions would become worse.

However, according to the present invention, the dummy layer does exist on the first active layer, so the ions that are contained in the plasma strike the dummy layer during the etching. Thus, during the process, the first active layer can be protected from the defects within the grain boundaries of the grains (particles) of the first active layer that are caused by the plasma. Note that according to the semiconductor manufacturing method, neither an expensive ion injection unit nor a plasma doping process is required to form the source and drain regions, so the semiconductor manufacturing method has an advantage in that the manufacturing cost can be reduced.

The specified conditions may include a selection ratio and an etching time. Specifically, the selection ratio of the photoresist film to the second active layer may be set to approximately 1:1 for the etching, and the etching time may be set such that the first active layer and the second active layer will reside in approximately the same plane, while the dummy layer will remain on top of the first active layer.

### BRIEF DESCRIPTION OF THE DRAWINGS

FIG. 1A is a sectional view of a device that shows a process of a semiconductor manufacturing method according to an embodiment of the present invention;

FIG. 1B is a sectional view of a device that shows a process of a semiconductor manufacturing method according to the embodiment;

FIG. 1C is a sectional view of a device that shows a process of a semiconductor manufacturing method according to the embodiment;

FIG. 1D is a sectional view of a device that shows a process of a semiconductor manufacturing method according to the embodiment;

FIG. 1E is a sectional view of a device that shows a process of a semiconductor manufacturing method according to the embodiment;

FIG. 2A is a sectional view of a device that shows a process of a semiconductor manufacturing method according to the embodiment;

FIG. 2B is a sectional view of a device that shows a process of a semiconductor manufacturing method according to the embodiment;

FIG. 2C is a sectional view of a device that shows a process of a semiconductor manufacturing method according to the embodiment;

FIG. 2D is a sectional view of a device that shows a process of a semiconductor manufacturing method according to the embodiment;

FIG. 3A is a sectional view of a device that shows a process of a semiconductor manufacturing method according to the embodiment;

FIG. 3B is a sectional view of a device that shows a process of a semiconductor manufacturing method according to the embodiment;

FIG. 3C is a sectional view of a device that shows a process of a semiconductor manufacturing method according to the embodiment;

FIG. 3D is a sectional view of a device that shows a process of a semiconductor manufacturing method according to the embodiment;

FIG. 4A is a sectional view of a device that shows a process of a semiconductor manufacturing method according to the embodiment;

FIG. 4B is a sectional view of a device that shows a process of a semiconductor manufacturing method according to the embodiment;

FIG. 4C is a sectional view of a device that shows a process of a semiconductor manufacturing method according to the embodiment; and

FIG. 4D is a sectional view of a device that shows a process of a semiconductor manufacturing method according to the embodiment.

### DETAILED DESCRIPTION OF THE PREFERRED EMBODIMENTS

A thin film transistor (TFT) process (a semiconductor manufacturing method) according to an embodiment of the present invention will be explained below with reference to the attached drawings. Note that in the explanation below and in the attached drawings, configuring elements that have the same structure and function are assigned the same reference numerals, and each will be explained only once.

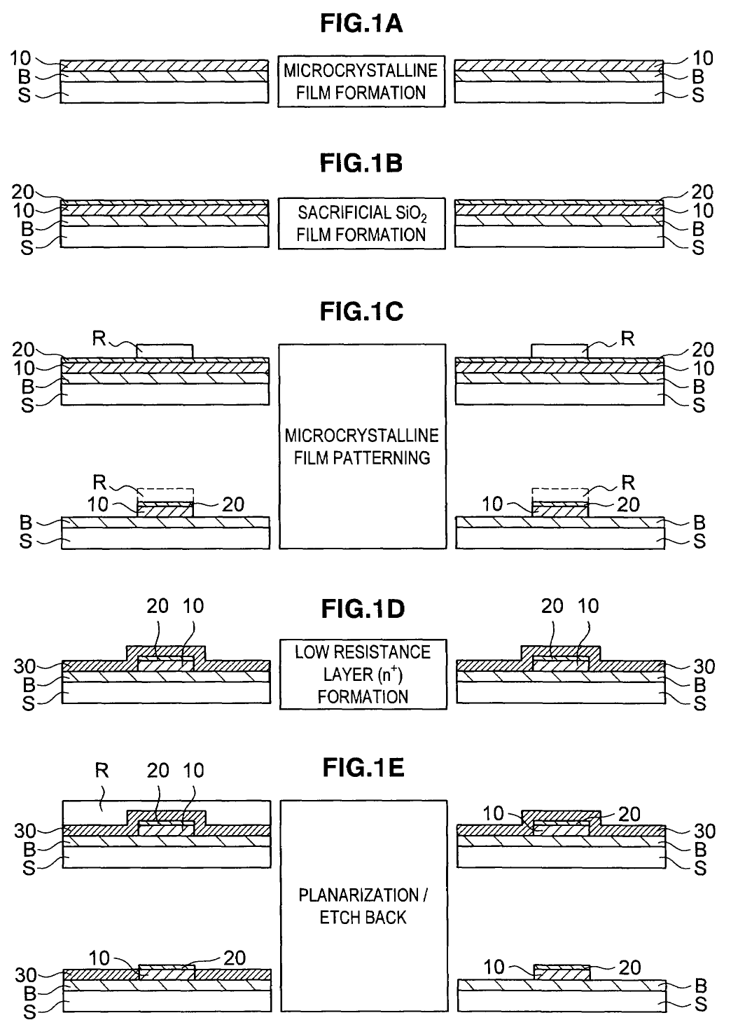

In the TFT process according to the present embodiment, the thin film transistor is manufactured using a microcrystalline film. The process manufactures the thin film transistor with a top gate structure in which a gate electrode is disposed on the opposite side of a glass substrate from the microcrystalline film. The top gate type TFT process is shown in FIGS. 1 to 4. The left side of each figure shows the n-channel TFT process, and the right side shows the p-channel TFT process.

1. Formation of First Active Layer

As shown in FIG. 1A, in the top gate type TFT process, a microcrystalline film 10 is built up on a glass substrate S, with a barrier layer B intervening. The microcrystalline film 10 is the equivalent of a first active layer that functions as a channel region. A condition of the film formation process is that the maximum temperature is restricted to no greater than 600° C. due to the deformation temperature of the glass substrate S. In the present embodiment, a microwave plasma processing apparatus is used to form the microcrystalline film 10 with good quality on a large glass substrate at a temperature not greater than 600° C.

The microcrystalline film 10 is formed by exciting a mixed gas containing silane (SiH₄) to generate a plasma, then using the generated plasma in a low-pressure chemical vapor deposition (CVD) process. Because the microcrystalline film 10 has excellent crystallinity, an annealing process and a laser recrystallization process are not required. Accordingly, if the microcrystalline film 10 is used for the TFT channel region, the carrier mobility is higher than when an amorphous silicon film is used. This makes it possible to achieve better operating characteristics at the same time that it lowers the cost.

In a case where the laser recrystallization process is used, for example, as well as in cases where a high-temperature process is used, such as where a high-temperature polysilicon film is used instead of the microcrystalline film 10, there is a possibility that impurities from the substrate, such as heavy metals and the like, will be mixed into the microcrystalline film 10. The barrier layer B between the glass substrate S and the microcrystalline film 10 is provided to prevent this from happening. Accordingly, the barrier layer B is not required in a case where only low-temperature processing in which the maximum temperature during the process is not greater than 600° C. is performed.

Note that in a case where the substrate is formed from a material with a high melting point, such as quartz or the like, the first active layer is not limited to being an as-deposited (as-deposited polysilicon) film that is formed by using the plasma process described above, but may also be an amorphous silicon (a-Si) film that is formed by deposition, then annealed by one of laser annealing and another annealing process.

2. Formation of Dummy Layer (Sacrificial Layer)

A sacrificial silicon oxide (SiO₂) film 20 is formed in a second process, as shown in FIG. 1B. The sacrificial silicon oxide film 20 may be formed by plasma CVD using a mixed gas of silane (SiH₄) and nitrous oxide (N₂O), for example. The sacrificial silicon oxide film 20 is used to protect a surface boundary of the microcrystalline film 10 during patterning and etch back of the first active layer, which are explained below. The sacrificial silicon oxide film 20 thus functions as a dummy layer (that is, a sacrificial layer) that is removed during the TFT manufacturing process.

3. Patterning of the First Active Layer

As shown in the upper part of FIG. 1C, after the sacrificial silicon oxide film 20 is formed, the glass substrate S is rotated at high speed by a spinner and coated with a photoresist film R that reacts to ultraviolet light. After the photoresist film R is applied, it is hardened by a heat treatment, and the glass substrate S is exposed to ultraviolet light through a mask. When the glass substrate S is immersed in a developing fluid, portions of the photoresist film R that were exposed remain, and unexposed portions are washed away.

Next, as shown in the lower part of FIG. 1C, the portions of the sacrificial silicon oxide film 20 and the microcrystalline film 10 that are uncovered by the removal portions of the photoresist film R are removed by etching, using buffered fluorinated acid as an etching fluid. An etching gas may also be used instead of the buffered fluorinated acid. Then the photoresist film R undergoes ashing by one of an oxygen (O₂) plasma and a plasma that is created from a mixed gas that contains oxygen (O₂) gas and carbon tetrafluoride (CF₄) gas.

4. Formation of Low Resistance Layer (n-Channel)

Next, as shown in FIG. 1D, a low resistance layer is formed by using plasma CVD to deposit a doped silicon (n⁺) film 30 that is doped with boron. The low resistance layer is the equivalent of a second active layer that functions as a source region and a drain region of the n-channel TFT.

5. Planarization/Etch Back

Next, as shown in the upper part of FIG. 1E, the entire surface of the doped silicon (n⁺) film 30 is coated with a photoresist film R that reacts to ultraviolet light. This is done by using a spinner to rotate the glass substrate S and planarizing the photoresist film R. The photoresist film R is then hardened by a heat treatment. Only the n-channel side is exposed to ultraviolet light, so the photoresist film R on the p-channel side, which is not exposed to ultraviolet light, is removed.

Next, etching is performed under process conditions in which the etching rate of the sacrificial silicon oxide film 20 is low and the etching selection ratio of the photoresist film R to the doped silicon (n⁺) film 30 is approximately 1:1. Specifically, as shown in the lower part of FIG. 1E, controlling the etching time under the process conditions described above means that the photoresist film R and the doped silicon (n⁺) film 30 are etched at the same etching rate on the n-channel side (the left side). When the specified etching time elapses, the sacrificial silicon oxide film 20 is in an uncovered state, and the source and drain regions of the doped silicon (n⁺) film 30, as well as the channel region of the microcrystalline film 10, are in an approximately planarized state.

At the same time that the n-channel side is etched, the doped silicon (n⁺) film 30 is etched on the p-channel side (the right side) as well. When the etching is finished, the doped silicon (n⁺) film 30 has been completely removed, the sacrificial silicon oxide film 20 is left in an uncovered state in which it serves as a stopper, and the microcrystalline film 10 remains on the substrate.

6. Formation of Silicon Nitride (SiN) Film

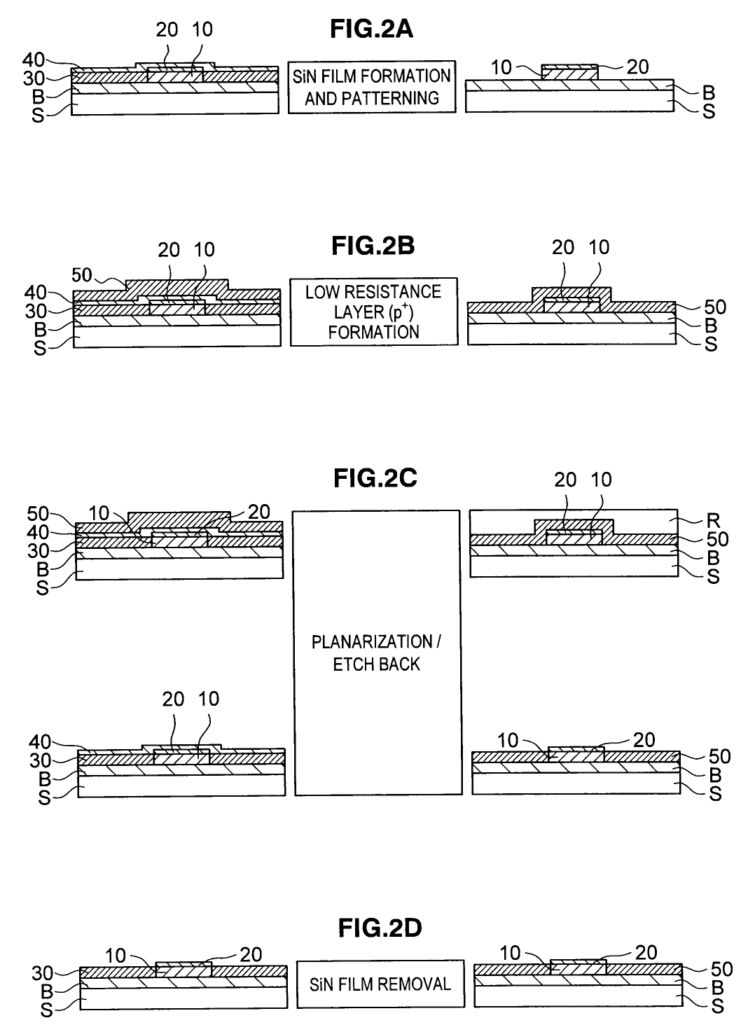

Next, as shown in FIG. 2A, a plasma that is formed by exciting a mixed gas of silane (SiH₄) and ammonia (NH₃), for example, is used to form a silicon nitride (SiN) film 40 that serves as a stopper layer. The silicon nitride (SiN) film 40 is then patterned.

7. Formation of Low Resistance Layer (p-Channel)

Next, as shown in FIG. 2B, a low resistance layer is formed by using plasma CVD to deposit a doped silicon (p⁺) film 50 that is doped with phosphorus. The low resistance layer is the equivalent of a second active layer that functions as a source region and a drain region of the p-channel TFT.

8. Planarization/Etch Back

Next, as shown in the upper part of FIG. 2C, the entire surface of the glass substrate S is coated with a photoresist film R that reacts to ultraviolet light. This is done by using a spinner to rotate the glass substrate S and planarizing the photoresist film R. The photoresist film R is then hardened by a heat treatment. Only the p-channel side is exposed to ultraviolet light, so the photoresist film R on the n-channel side, which is not exposed to ultraviolet light, is removed.

Next, etching is performed under process conditions in which the etching rate of the sacrificial silicon oxide film 20 is low and the etching selection ratio of the photoresist film R to the doped silicon (p⁺) film 50 is approximately 1:1. Specifically, as shown in the lower part of FIG. 2C, controlling the etching time under the process conditions described above means that the photoresist film R and the doped silicon (p⁺) film 50 are etched at the same etching rate on the p-channel side (the right side). When the specified etching time elapses, the sacrificial silicon oxide film 20 is left uncovered, and the source and drain regions of the doped silicon (p⁺) film 50, as well as the channel region of the microcrystalline film 10, are in an approximately planarized state. At the same time, the doped silicon (p⁺) film 50 is etched on the n-channel side (the right side) as well. When the etching is finished, the doped silicon (p⁺) film 50 has been completely removed, the silicon nitride film 40 is left in an uncovered state in which it serves as a stopper.

9. Removal of the Silicon Nitride (SiN) Film 40

Next, as shown in FIG. 2D, the silicon nitride film 40 is removed by etching that uses a hot concentrated phosphoric acid solution, for example.

10. Island Patterning

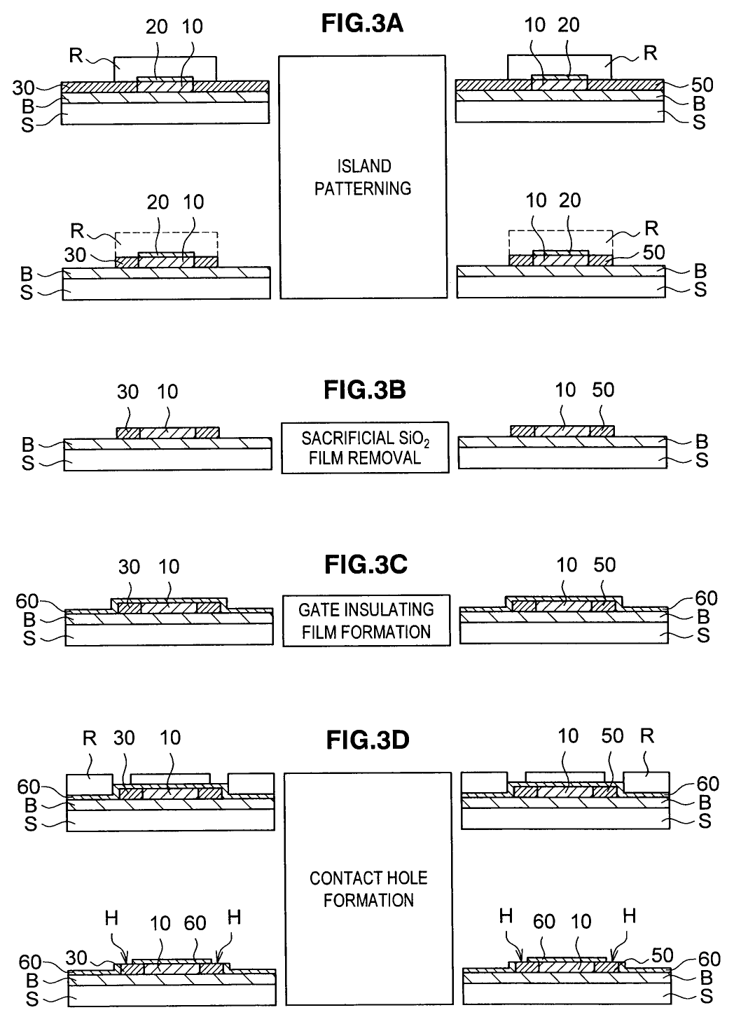

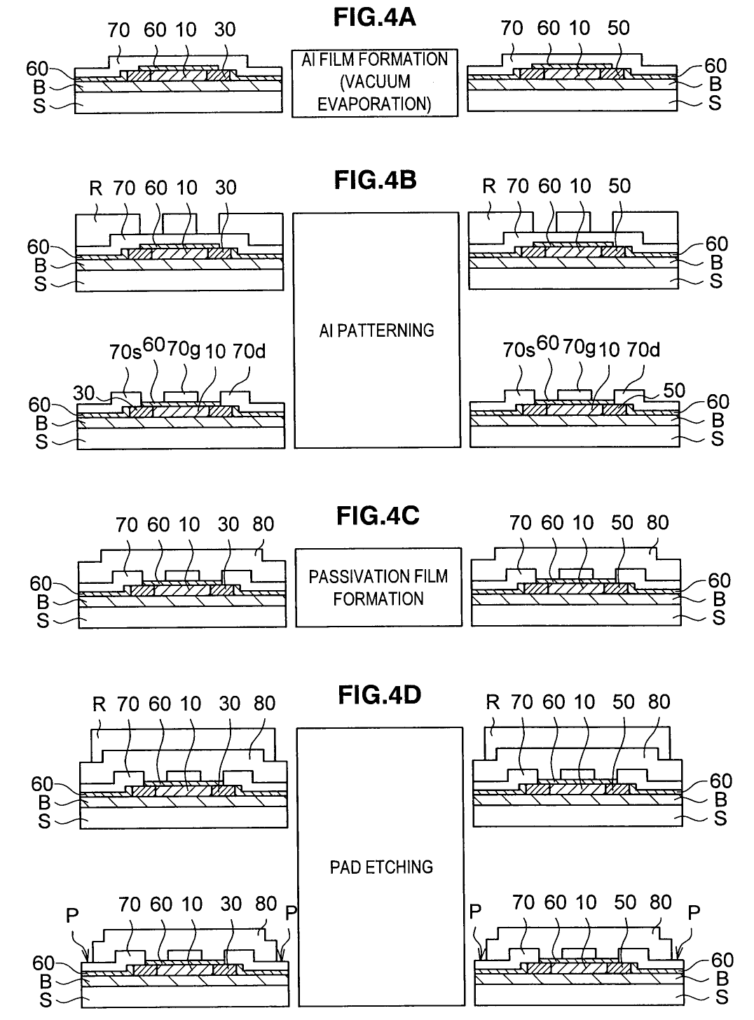

Each of the processes shown in FIGS. 3 and 4 is performed in a identical manner on both the p-channel side and the n-channel side. First, as shown in the upper part of FIG. 3A, the n-channel TFT and the p-channel TFT are coated with a photoresist film R and exposed to light. As shown in the lower part of FIG. 3A, island-shaped patterning of the source and drain regions and the channel region is performed by etching the uncovered portions, after which the photoresist film R is removed by ashing.

11. Removal of the Sacrificial Silicon Oxide (SiO₂) Film 20

Next, as shown in FIG. 3B, the sacrificial silicon oxide (SiO₂) film 20 is removed by etching that uses a dilute HF aqueous solution.

12. Formation of Gate Insulating Film

After the sacrificial silicon oxide film 20 has been removed, a silicon oxide (SiO₂) film (a gate insulating film 60) is formed by plasma CVD using a mixed gas of silane (SiH₄) and nitrous oxide (N₂O), for example, to act as insulation between electrically conductive layers. Note that a silicon nitride (SiN) film may also be used for the gate insulating film 60.

13. Formation of Contact Holes

Next, contact holes H are formed in the tops of the source and drain regions of the n-channel TFT and the p-channel TFT (the doped silicon films 30, 50) by applying a photoresist film R as shown in the upper part of FIG. 3D and exposing it to light, then etching the uncovered portions and ashing the photoresist film R, as shown in the lower part of FIG. 3D.

14. Formation of Aluminum Film for Wiring

Next, as shown in FIG. 4A, an aluminum film 70 for wiring is formed by sputtering, for example.

15. Aluminum Patterning

Patterning of the aluminum film 70 for wiring is performed by applying a resist as shown in the upper part of FIG. 4B and exposing it to light, then performing etching as shown in the lower part of FIG. 4B. This process forms gate electrodes 70g in positions across from the gate insulating film 60 that face the microcrystalline film 10. It also forms source and drain electrodes 70s, 70d that are respectively connected to the source and drain regions through the contact holes H.

16. Formation of Passivation Film

In order to protect the n-channel TFT and the p-channel TFT that are formed on the glass substrate S (the barrier layer B) as described above, an insulating film such as a silicon nitride film or the like is formed by plasma CVD as a passivation film 80 on each of the TFTs, as shown in FIG. 4C.

17. Pad Etching

Last, a pad portion P is formed by applying a photoresist film R as shown in the upper part of FIG. 4D and exposing it to light, then etching the uncovered portions and ashing the photoresist film R, as shown in the lower part of FIG. 4D.

According to the semiconductor manufacturing method described above for manufacturing the coplanar type of n-channel thin film transistor and p-channel thin film transistor, a microcrystalline film (the sacrificial silicon oxide film 20) is formed as a sacrificial film directly on top of the first active layer, such that during the etching, ions that are contained in the plasma strike the sacrificial silicon oxide film 20. This makes it possible to protect the first active layer during the process by preventing the plasma from causing defects within the grain boundaries of grains (particles) in the first active layer.

According to the semiconductor manufacturing method, during the etching, the etching time is controlled such that the etching process is performed only for a predetermined specified etching time. Thus, as shown in FIGS. 1E and 2C, the photoresist film R and the second active layers (the doped silicon films 30, 50) are etched at the same etching rate, and the etching rate is kept uniform within the plane. With the dummy layer (the sacrificial silicon oxide film 20) remaining on top of the first active layer (the microcrystalline film 10), the first active layer (the microcrystalline film 10) and the second active layers (the doped silicon films 30, 50) are formed in approximately the same plane. Thus the surface of the channel layer (the microcrystalline film 10), which is the most important layer, is not uncovered during the process, and it is possible to form the active regions of the coplanar type thin film transistor such that the drain and source regions are provided alongside the channel region, to which they are directly attached. This increases the controllability of the surface boundary between the first active layer and the insulating layer between the layers and keeps the mobility and the on/off ratio high, making it possible to manufacture the thin film transistor such that it is capable of high-speed processing with low electric power consumption.

Furthermore, by using the microcrystalline film 10 for the first active layer, the semiconductor manufacturing method can limit the temperature during the process to no greater than 600° C., in contrast to a case where the first active layer is a high-temperature polysilicon film for which the maximum temperature during the process is 1000° C. or higher. This makes it unnecessary to use an expensive quartz for the substrate and makes it possible to use the glass substrate, for which the maximum processing temperature must be kept to no greater than 600° C., due to the deformation temperature of the glass. Using the inexpensive glass substrate makes it possible to deal flexibly with larger substrate surface areas while keeping the cost down.

In addition, when the microcrystalline film 10 is used for the first active layer, the annealing process and the laser recrystallization process are rendered unnecessary. The elimination of these processes makes it possible to reduce the cost.

Moreover, according to the semiconductor manufacturing method, neither an expensive ion injection unit nor a plasma doping process is required to form the source and drain regions, so the manufacturing cost can be reduced.

Note that the formation process for the microcrystalline film 10, shown in FIG. 1A, is equivalent to a first process that forms the first active layer that becomes the channel region on top of the substrate. The formation process for the sacrificial silicon oxide film 20, shown in FIG. 1B, is equivalent to a second process that forms the dummy layer on top of the first active layer. The buildup processes for the low resistance layers (the doped silicon films 30, 50), shown in FIGS. 1D and 2B, are equivalent to a third process that builds up the second active layers that become the source region and the drain region in a state in which the surface boundary of the first active layer is protected by the dummy layer that was formed by the second process.

The planarization processes shown in the upper part of FIG. 1E and the upper part of FIG. 2C are equivalent to a fourth process that applies the photoresist film R on top of the second active layer and planarizes the applied photoresist film R. The etching processes shown in the lower part of FIG. 1E and the lower part of FIG. 2C are equivalent to a fifth process that is performed after the fourth process under specified conditions, in a state in which the dummy layer is uncovered, and that performs the etching until the first active layer and the second active layer reside in approximately the same plane.

The removal process for the sacrificial silicon oxide film 20, shown in FIG. 3B, is equivalent to a sixth process that is performed after the fifth process and that removes the dummy layer. The formation process for the gate insulating film 60, shown in FIG. 3C, is equivalent to a seventh process that is performed after the sixth process and that forms the insulating layer between the layers.

In the present embodiment, the sacrificial silicon oxide film 20 is used for the dummy layer, but the film that is used for the dummy layer is not limited to this example. The film may also be an insulating film, such as a silicon nitride film or the like, for example, that has a lower etching rate than do the photoresist film and the second active layer and that can function as a protective layer to protect the device from impurities and moisture.

Further, in the present embodiment, the dummy layer is removed after the island patterning is performed (refer to FIGS. 3A and 3B), but the present embodiment is not limited to this example, and the dummy layer may also be removed after the patterning of the first active layer is performed (refer to FIG. 1C), for example. However, because the dummy layer is used as a stopper for the etching, in order to protect the surface of the first active layer adequately during the process, it is preferable to remove the dummy layer after the silicon nitride film 40 is removed, as shown in FIG. 2D, and it is most desirable to remove the dummy layer after the island patterning, as shown in FIG. 3A is performed.

It is also possible for each of the layers that is built up during the process by the plasma CVD processing to be formed by sputtering instead.

In a case where a substrate with a high melting point is used, the first active layer is not limited to being the microcrystalline film 10, but may also be a high-temperature polysilicon film, for example. The first active layer is also not limited to being an as-deposited film (a film in the state in which it was formed), but may also be an amorphous silicon film (an a-Si film) that is formed, then annealed by one of laser annealing and another annealing process.

For example, in a case where a high-temperature polysilicon film is used for the first active layer, the gate wiring is formed in the thin film transistor with the top gate structure after the high-temperature polysilicon film, which requires a high process temperature, and the gate insulating film are formed. Thus a high-temperature state, such as that that occurs during the formation of the high-temperature polysilicon film, does not occur in the processes that are performed after the gate wiring is formed. Therefore, the thin film transistor with the top gate structure has an advantage in that it does not require that the metal material for the gate be limited to a metal film with a high melting point.

In the present embodiment, the barrier layer B is provided on top of the glass substrate S, but in a case where no high-temperature processes are performed, the barrier layer B may be omitted. In a case where high-temperature processes are performed, the barrier layer B must be provided, because the barrier layer B prevents impurities from the glass substrate S, such as heavy metals and the like, from being mixed into the active regions.

Using a semiconductor manufacturing apparatus that manufactures the thin film transistor using the semiconductor manufacturing method explained above makes it possible to increase the controllability of the surface boundary between the first active layer and the insulating layer between the layers and to keep the mobility and the on/off ratio high, making it possible to manufacture the thin film transistor such that it is capable of high-speed processing with low electric power consumption. Furthermore, using the microcrystalline film 10 for the channel layer makes it possible to form the thin film transistor on the inexpensive glass substrate S by maintaining the temperature during the process at no greater than 600° C.

Each process in the embodiment explained above and the relationships between the processes will be summarized briefly below. For example, during the etching, the selection ratio of the photoresist film R to the second active layers may be set to approximately 1:1, and the etching time may be set such that the first active layer and the second active layers are formed in approximately the same plane, while the dummy layer remains on the first active layer.

This means that the process time is controlled such that the etching process is performed only for the predetermined specified etching time. Accordingly, as shown in the upper part of FIG. 1E, the photoresist film R and the second active layer (the doped silicon film 30) are etched at the same etching rate, and the etching rate is kept uniform within the plane. As shown in the lower part of FIG. 1E, with the dummy layer (the sacrificial silicon oxide film 20) remaining on the first active layer (the microcrystalline film 10), the first active layer (the microcrystalline film 10) and the second active layer (the doped silicon film 30) are formed in approximately the same plane. Thus the surface of the channel layer (the microcrystalline film 10), which is the most important layer, is not uncovered during the process, and it is possible to form the source region and the drain region such that they are alongside and directly attached to the channel region. This increases the controllability of the surface boundary between the first active layer and the insulating layer between the layers and keeps the mobility and the on/off ratio high, making it possible to manufacture the thin film transistor such that it is capable of high-speed processing with low electric power consumption.

the photoresist film may be selectively applied on the second active layer for a selected one of the n-channel and the p-channel thin film transistors in the fourth process, and the fifth process may be applied only for the selected one of the n-channel and the p-channel thin film transistors. The second active layer for the other of the n-channel and p-channel thin film transistors may be etched away in the fifth process. The third process may be repeated while the first and the second active layers and the dummy layer for the selected one of the n-channel and p-channel thin film transistors are covered by a protective film.

Thus, the etching is performed only for the predetermined etching time in a state in which the applied photoresist film R has been removed from either one of the n-channel thin film transistor and the p-channel thin film transistor. Accordingly, on the side where the photoresist film R has been removed, the entire second active layer that was built up before the photoresist film R was applied is etched, returning the device to the state prior to the buildup of the second active layer. On the side where the photoresist film R has not been removed, the first active layer and the second active layer are formed in approximately the same plane. Even in this case, because the dummy layer is provided directly on top of the first active layer, damage to the surface of the first active layer by the plasma can be avoided. Sequentially performing the removal of the photoresist film R twice, once each for the n-channel side and the p-channel side (in no particular order), makes it possible to avoid damage to the surface of the first active layer of both channels. It also makes it possible to use identical processes to form the semiconductor layers of the coplanar type n-channel thin film transistor and p-channel thin film transistor that have the structure in which the source and drain regions are alongside and directly attached to the channel region.

The sixth process, which removes the dummy layer, may be performed after the fifth process. The seventh process, which forms a gate insulator layer on the first active layer, may be performed after the sixth process.

Because the insulating layer between the layers is thus formed on top of the channel layer immediately after the dummy layer is removed, the channel layer is not left uncovered during the process. This increases the controllability of the surface boundary between the channel layer and the insulating layer between the layers and keeps the mobility and the on/off ratio high, making it possible to manufacture the thin film transistor such that it is capable of high-speed processing with low electric power consumption.

The first active layer may be formed of the microcrystalline semiconductor. The crystal grains of the microcrystalline film 10 are smaller than those of a polysilicon film, and within a single grain (within the grain boundary), the carriers made up of electrons and holes move in the same regular periodic potential as in a single crystal, so they can move around freely. On the other hand, the grain boundary acts as a barrier to the movement of the electrons and holes, impeding the movement of the carriers. However, because the crystal grains of the microcrystalline film 10 are smaller than those of the polysilicon film, the barrier is far smaller than that in the polysilicon film. In contrast, an amorphous silicon film has an irregularly arranged structure, so the potential energy of the electrons and holes is distributed irregularly. The carriers must therefore move in the irregularly distributed potential, so their mobility is lower than in the microcrystalline film 10.

Further, in contrast to the high-temperature polysilicon film, for which the temperature during the formation process reaches 1000° C. or higher, the temperature in the vicinity of the substrate during the formation of the microcrystalline film 10 can be limited to no greater than 600° C., so an annealing process is not required after the film is formed. This eliminates the need to use expensive quartz for the substrate and makes it possible to use the glass substrate 20, for which the maximum temperature during the process must be limited to no greater than 600° C. because of the deformation temperature of the glass. Thus, if the microcrystalline film 10 is used for the first active layer, it is not only possible to manufacture a high-quality transistor with high mobility, but is also possible to deal flexibly with larger substrate surface areas while keeping the cost down by using the glass substrate 20.

Note that the polysilicon film has larger grains and higher mobility than the amorphous silicon film and the microcrystalline film 10. This means that the polysilicon TFT achieves higher carrier mobility in both the p type and the n type, and that its current drive capacity (mobility) is greater than that of the amorphous silicon TFT by two orders of magnitude or more. On the other hand, the amorphous silicon film and the microcrystalline film 10 are polycrystalline, so processes such as an annealing process and recrystallization by laser are required. Accordingly, if the microcrystalline film 10 is used as is, the recrystallization can be omitted and the cost can be reduced, but if performing the laser annealing of one of the amorphous silicon film and the microcrystalline film 10 adds a process that converts the microcrystalline film into the polysilicon film, the polysilicon film can be used instead of the microcrystalline film 10.

The dummy layer may be formed from one of a silicon oxide film and a silicon nitride film. The one of the silicon oxide film and the silicon nitride film is an insulating film (a dielectric film) and can function as a protective film to protect the device from being struck by ions in the plasma, as well as from impurities and moisture.

The thin film transistor may also be manufactured by the top gate process. For example, in a case where a high-temperature polysilicon film is used for the first active layer, the gate wiring is formed in the thin film transistor with the top gate structure after the high-temperature polysilicon film, which requires a high process temperature, and the gate insulating film are formed. Thus a high-temperature state, such as that that occurs during the formation of the high-temperature polysilicon film, does not occur in the processes that are performed after the gate wiring is formed. Therefore, the thin film transistor with the top gate structure has an advantage in that it does not require that the metal material for the gate be limited to a metal film with a high melting point.

Using a semiconductor manufacturing apparatus that manufactures the thin film transistor using the semiconductor manufacturing method explained above makes it possible, because the surface of the channel layer is protected during the process, to increase the controllability of the surface boundary between the first active layer and the insulating layer between the layers and to keep the mobility and the on/off ratio high, making it possible to manufacture the thin film transistor such that it is capable of high-speed processing with low electric power consumption. Furthermore, using the microcrystalline film 10 for the channel layer makes it possible to form the thin film transistor on the inexpensive glass substrate S by maintaining the temperature during the process at no greater than 600° C.

Furthermore, incorporating into a display unit the thin film transistor that is manufactured by the semiconductor manufacturing apparatus makes it possible to produce the display unit such that it is capable of high-speed processing with low electric power consumption.

According to the embodiment of the present invention as explained above, the thin film transistor can be manufactured such that the surface of the channel layer is protected during the process.

In the embodiment described above, the various parts of the operation are interrelated, and they can be rearranged as a series of operations, taking their interrelationship into account. This sort of rearrangement makes it possible to take the embodiment of the present invention as the semiconductor manufacturing method for manufacturing the thin film transistor and make an embodiment of the present invention as the semiconductor manufacturing apparatus that manufactures the thin film transistor by using the semiconductor manufacturing method.

In the embodiment described above, the various films are formed by plasma CVD using a microwave plasma processing apparatus. Thus the semiconductor manufacturing apparatus that manufactures the thin film transistor by using the semiconductor manufacturing method may also be a plasma processing apparatus that is capable of forming a film by using a plasma that is generated by using microwave field energy to excite various types of gases. In this process, microwaves with a power of 1 to 8 watts per square centimeter may be supplied within a chamber of a specified size. However, the semiconductor manufacturing apparatus is not limited to being the microwave plasma processing apparatus and may also be, for example, a capacitive coupling type (parallel plate type) plasma processing apparatus and an inductive coupling type plasma processing apparatus.

Incorporating into the display unit the thin film transistor that is manufactured by the semiconductor manufacturing apparatus also makes it possible to produce the display unit such that it is capable of high-speed processing with low electric power consumption. The display unit may be an organic electroluminescence (EL) display, a plasma display, a liquid crystal display (LCD), or the like.

The size of the substrate that is processed by the semiconductor manufacturing apparatus is 730 millimeters by 920 millimeters and larger. The semiconductor manufacturing apparatus can perform continuous film formation processing on a substrate of 730 mm×920 mm G4.5 substrate size (chamber internal dimensions: 1000 mm×1190 mm), the 1100 mm×1300 mm G5 substrate size (chamber internal dimensions: 1470 mm×1590 mm), and larger.

The processed object that is processed by the semiconductor manufacturing apparatus as described above is not limited to the glass substrate, but may also be a silicon wafer or the like with a diameter of 200 millimeters, 300 millimeters, or the like.

It should be understood by those skilled in the art that various modifications, combinations, sub-combinations and alterations may occur depending on design requirements and other factors insofar as they are within the scope of the appended claims or the equivalents thereof.

For example, in the embodiment described above, a method was described in which both channels of the coplanar type n-channel thin film transistor and p-channel thin film transistor are manufactured as a pair, but the semiconductor manufacturing method according to the present invention is not limited to this example. The semiconductor manufacturing method may also be a method that manufactures only the n-channel thin film transistor, and it may also be a method that manufactures only the p-channel thin film transistor. In the case of the method that manufactures only the n-channel thin film transistor, it is permissible for only the processes shown in FIGS. 1A to 1E, FIGS. 3A to 3D, and FIGS. 4A to 4D to be performed. In the case of the method that manufactures only the p-channel thin film transistor, it is permissible for only the processes shown in FIGS. 1A to 1C, FIGS. 2B to 2C, FIGS. 3A to 3D, and FIGS. 4A to 4D to be performed.

The substrate that is used for the present invention may be, for example, a substrate that is used in an organic EL display, a plasma display, a liquid crystal display, or the like. The semiconductor manufacturing apparatus according to the present invention may be any unit that can form the thin film transistor on this sort of substrate by using the semiconductor manufacturing method described above.

What is claimed is:

1. A semiconductor manufacturing method for manufacturing at least one of a coplanar type n-channel thin film transistor and a coplanar type p-channel thin film transistor, comprising:
a first process that forms, on a substrate, a first active layer that becomes a channel region;
a second process that forms a dummy layer on the first active layer; and
a third process that, with a surface boundary of the first active layer in a state of being protected by the dummy layer, builds up a second active layer that becomes a source region and a drain region.

2. The semiconductor manufacturing method according to claim 1, further comprising:
a fourth process that applies a photoresist film on the second active layer and planarizes the applied photoresist film; and
a fifth process that, after the fourth process and in a state in which the dummy layer is uncovered, performs etching under specified conditions until the surfaces of the first active layer and the second active layer reside in approximately the same plane.

3. The semiconductor manufacturing method according to claim 2,
wherein the specified conditions include a selection ratio and an etching time,
the selection ratio of the photoresist film to the second active layer is set to approximately 1:1 for the etching, and
the etching time is set such that the surfaces of the first active layer and the second active layer reside in approximately the same plane, while the dummy layer remains on the first active layer.

4. The semiconductor manufacturing method according to claim 2,
wherein the photoresist film is selectively applied on the second active layer for a selected one of the n-channel and the p-channel thin film transistors in the fourth process, and
wherein the fifth process is applied only for the selected one of the n-channel and the p-channel thin film transistors.

5. The semiconductor manufacturing method according to claim 4,
wherein the second active layer for the other of the n-channel and p-channel thin film transistors is etched away in the fifth process.

6. The semiconductor manufacturing method according to claim 5,
wherein the third process is repeated while the first and the second active layers and the dummy layer for the selected one of the n-channel and p-channel thin film transistors are covered by a protective film.

7. The semiconductor manufacturing method according to claim 2,
a sixth process that removes the dummy layer after the fifth process.

8. The semiconductor manufacturing method according to claim 7,
a seventh process that forms a gate insulator layer on the first active layer after the sixth process.

9. The semiconductor manufacturing method according to claim 1,
wherein the first active layer is formed of microcrystalline semiconductor.

10. The semiconductor manufacturing method according to claim 1,
wherein the dummy layer is comprised of at least one of a silicon oxide film and a silicon nitride film.

11. The semiconductor manufacturing method according to claim 1,
wherein the thin film transistor is of the type of a top gate.

12. The semiconductor manufacturing method according to claim 2,
wherein any portion of the n-channel and p-channel thin film transistors is not subjected to a heat treatment at a temperature exceeding 600° C.

13. A semiconductor manufacturing apparatus that manufactures a thin film transistor by using a semiconductor manufacturing method; the semiconductor manufacturing method including:
a first process that forms, on a substrate, a first active layer that becomes a channel region;
a second process that forms a dummy layer on the first active layer; and
a third process that, with a surface boundary of the first active layer in a state of being protected by the dummy layer, builds up a second active layer that becomes a source region and a drain region.

14. A display unit that includes thin film transistors that are manufactured by the semiconductor manufacturing apparatus according to claim 13.
